(19) United States
(12) Patent Application Publication
(10) Pub. No.: US 2026/0107744 A1
(43) Pub. Date: Apr. 16, 2026

(54) GRINDING METHOD AND GROUND WAFER MANUFACTURING METHOD

(71) Applicant: DISCO CORPORATION, Tokyo (JP)

(72) Inventor: Yoshikazu Suzuki, Tokyo (JP)

(21) Appl. No.: 19/320,072

(22) Filed: Sep. 5, 2025

(30) Foreign Application Priority Data
Oct. 11, 2024 (JP) 2024- 178847

(51) Int. Cl. H01L 21/02; B24B 5/14; B24B 5/24

(52) U.S. Cl. CPC H10P 90/123; B24B 5/14; B24B 5/24

(57) ABSTRACT

A method for grinding a workpiece with a grinding apparatus including a holding table with a rotatable conical-shaped holding surface, a grinding unit including a spindle and grindstones, which grinds the workpiece by bringing the rotating grindstones into contact with the workpiece to thereby form a grinding surface lying along the holding surface, and a moving unit that moves the holding table and the grindstones relative to each other. The method includes holding the workpiece on the holding surface, grinding the workpiece by performing grinding feed where the holding table and the spindle approach each other along a rotational axis of the spindle with the workpiece and the grindstones contacting each other while the holding table and the spindle are independently rotated, and, after grinding the workpiece, stopping the grinding feed and moving the holding table and the spindle relative to each other while rotating the table and the spindle.

### BACKGROUND OF THE INVENTION

### FIELD OF THE INVENTION

The present invention relates to a method for grinding a workpiece such as a semiconductor wafer and a method for manufacturing a ground wafer.

### DESCRIPTION OF THE RELATED ART

Device chips to be mounted on electronic equipment such as mobile phones and personal computers are manufactured through processing of semiconductor wafers.

On one surface of a disc-shaped semiconductor wafer, a plurality of planned division lines (streets) are set in a lattice pattern, and devices such as integrated circuits (ICs) and large-scale integration (LSI) circuits are formed in respective rectangular areas partitioned by the planned division lines. The semiconductor wafer having the devices formed thereon is cut along each planned division line, so that the semiconductor wafer is divided into a plurality of device chips.

In recent years, in such manufacturing of device chips, wafers are thinned in order to reduce chips in size and weight. For example, in the process of manufacturing device chips as described above, the wafer having devices formed on a front surface thereof is ground at a back surface thereof, so that the entire wafer is thinned.

Examples of documents describing such a technology related to grinding of wafers include Japanese Patent Laid-open No. 2019-130637.

### SUMMARY OF THE INVENTION

Incidentally, it is preferable that, in grinding of a wafer, the wafer as a workpiece be uniform in thickness as much as possible and the surface of the wafer be flat as much as possible. However, depending on such conditions as the shape and kind of grindstones used in grinding, the material and shape of the wafer, the shape of a holding table that holds the wafer thereon, and the magnitude and distribution of force applied between the grindstones and the wafer in grinding, unfavorable irregularities are formed on the surface of the wafer as a result of the grinding in some cases.

Therefore, it is an object of the present invention to provide a grinding method and a ground wafer manufacturing method that can achieve a more favorable surface shape in a ground workpiece.

In accordance with an aspect of the present invention, there is provided a grinding method for grinding a workpiece by use of a grinding apparatus, the grinding apparatus including a holding table that has a holding surface of a conical surface shape and is rotatable about an axis intersecting the holding surface, a grinding unit that includes a spindle to which grindstones are attached and grinds the workpiece held on the holding surface of the holding table by bringing the grindstones into contact with the workpiece while causing the grindstones to rotate in such a manner as to form a grinding surface lying along the holding surface, and a moving unit that moves the holding table and the grindstones relative to each other, the grinding method including holding the workpiece on the holding surface of the holding table, grinding the workpiece held on the holding surface by performing grinding feed in which the moving unit causes the holding table and the spindle to approach each other in directions along a rotational axis of the spindle in a state in which the workpiece and the grindstones are in contact with each other while the holding table and the spindle are independently being rotated with respective rotational axes extending along each other, and, after the grinding the workpiece, stopping the grinding feed by the moving unit and moving the holding table and the spindle relative to each other in directions intersecting the rotational axis of the spindle while rotating the holding table and the spindle.

In the aspect of the present invention, preferably, in the grinding the workpiece, a part of a locus formed by the grindstones is located at a vertex of the workpiece that is held on the holding surface of the holding table and formed in a conical surface shape.

In the aspect of the present invention, preferably, in the moving the holding table and the spindle relative to each other in the directions intersecting the rotational axis of the spindle, the spindle and the holding table are moved relative to each other in directions along the grinding surface of the grindstones.

In the aspect of the present invention, preferably, in the moving the holding table and the spindle relative to each other in the directions intersecting the rotational axis of the spindle, the spindle and the holding table are separated from each other in the directions along the rotational axis of the spindle while being moved relative to each other in directions along the grinding surface of the grindstones.

In the aspect of the present invention, preferably, the grindstones include a resin bond as a bond material.

In accordance with another aspect of the present invention, there is provided a ground wafer manufacturing method for manufacturing a ground wafer by use of a grinding method for grinding a workpiece by use of a grinding apparatus, the grinding apparatus including a holding table that has a holding surface of a conical surface shape and is rotatable about an axis intersecting the holding surface, a grinding unit that includes a spindle to which grindstones are attached and grinds the workpiece held on the holding surface of the holding table by bringing the grindstones into contact with the workpiece while causing the grindstones to rotate in such a manner as to form a grinding surface lying along the holding surface, and a moving unit that moves the holding table and the grindstones relative to each other, the grinding method including holding the workpiece on the holding surface of the holding table, grinding the workpiece held on the holding surface by performing grinding feed in which the moving unit causes the holding table and the spindle to approach each other in directions along a rotational axis of the spindle in a state in which the workpiece and the grindstones are in contact with each other while the holding table and the spindle are independently being rotated with respective rotational axes extending along each other, and, after the grinding the workpiece, stopping the grinding feed by the moving unit and moving the holding table and the spindle relative to each other in directions intersecting the rotational axis of the spindle while rotating the holding table and the spindle. In this ground wafer manufacturing method, the workpiece is a platelike wafer.

With the grinding method and the ground wafer manufacturing method according to the aspects of the present invention, after the workpiece is ground, the grinding feed by the moving unit is stopped, and the holding table and the spindle are moved relative to each other in the directions intersecting the rotational axis of the spindle while being rotated. Accordingly, a further suitable surface shape can be realized on the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a grinding apparatus according to an embodiment;

FIG. 2 is a cross-sectional view illustrating a manner in which a workpiece (wafer) is ground by the grinding apparatus illustrated in FIG. 1;

FIG. 3 is a flowchart describing an example of a procedure related to the grinding of a workpiece (wafer) and manufacturing of a ground wafer by use of the grinding apparatus illustrated in FIG. 1;

FIG. 4 is a cross-sectional view schematically illustrating states of grindstones and the workpiece (wafer) during grinding;

FIG. 5 is a cross-sectional view schematically illustrating, as a reference example, exemplary states of the grindstones and the workpiece (wafer) in spark-out;

FIG. 6 is a cross-sectional view schematically illustrating, as a reference example, exemplary states of the grindstones and the workpiece (wafer) in escape cut;

FIG. 7 is a photograph depicting, as a reference example, an exemplary state of a surface of the workpiece (ground wafer) obtained after completion of a grinding step and a retracting step;

FIG. 8 is a chart illustrating a measurement result of the shape of the surface of the workpiece (ground wafer) depicted in FIG. 7;

FIG. 9 is a flowchart describing another example of the procedure related to the grinding of a workpiece (wafer) and the manufacturing of a ground wafer by use of the grinding apparatus illustrated in FIG. 1;

FIG. 10 is a cross-sectional view schematically illustrating other exemplary states of the grindstones and the workpiece (wafer) in spark-out;

FIG. 11 is a cross-sectional view schematically illustrating other exemplary states of the grindstones and the workpiece (wafer) in escape cut;

FIG. 12 is a photograph depicting another exemplary state of the surface of the workpiece (ground wafer) obtained after completion of the grinding step and the retracting step;

FIG. 13 is a chart illustrating a measurement result of the shape of the surface of the workpiece (ground wafer) depicted in FIG. 12;

FIG. 14 is a photograph depicting a further exemplary state of the surface of the workpiece (ground wafer) obtained after completion of the grinding step and the retracting step;

FIG. 15 is a chart illustrating a measurement result of the shape of the surface of the workpiece (ground wafer) depicted in FIG. 14;

FIG. 16 is a flowchart describing a further example of the procedure related to the grinding of a workpiece (wafer) and the manufacturing of a ground wafer by use of the grinding apparatus illustrated in FIG. 1;

FIG. 17 is a cross-sectional view schematically illustrating further exemplary states of the grindstones and the workpiece (wafer) in escape cut;

FIG. 18 is a photograph depicting a further exemplary state of the surface of the workpiece (ground wafer) obtained after completion of the grinding step and the retracting step; and

FIG. 19 is a chart illustrating a measurement result of the shape of the surface of the workpiece (ground wafer) depicted in FIG. 18.

### DETAILED DESCRIPTION OF THE PREFERRED EMBODIMENT

An embodiment of the present invention is hereinafter described in detail with reference to the accompanying drawings.

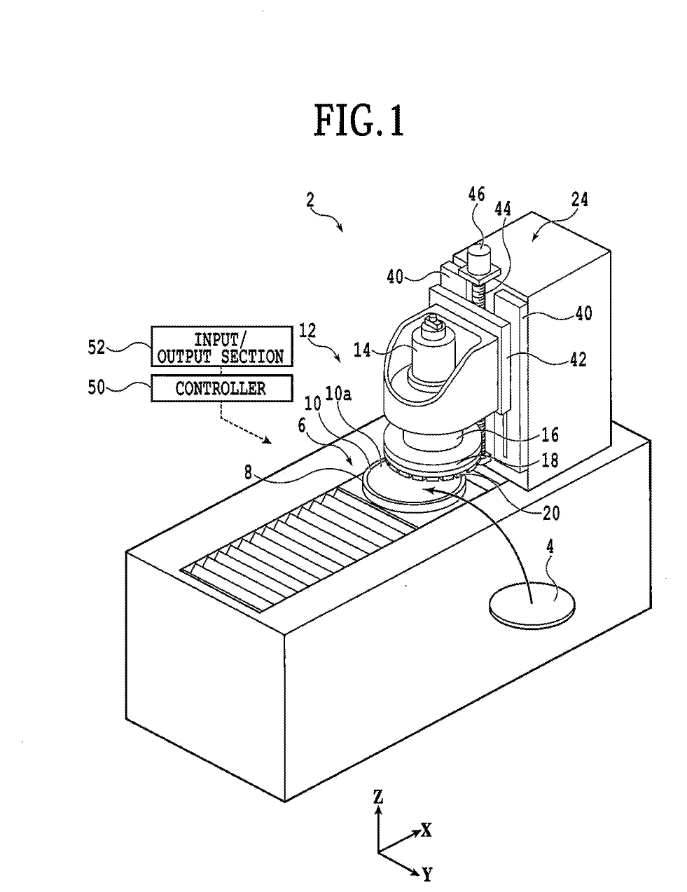

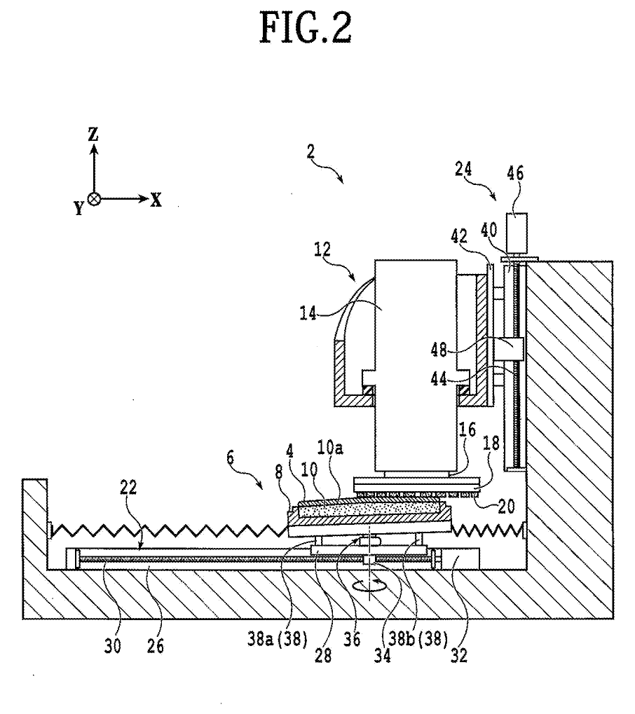

FIG. 1 is a perspective view illustrating an example of a grinding apparatus 2 according to the present embodiment. FIG. 2 is a cross-sectional view illustrating a manner in which a workpiece (wafer) 4 is ground by the grinding apparatus 2.

In FIG. 1 and FIG. 2, an X-axis direction, a Y-axis direction, and a Z-axis direction represent directions of three axes orthogonal to one another in a three-dimensional space. The X-axis direction (front-back direction) and the Y-axis direction (left-right direction) are horizontal directions orthogonal to each other. The Z-axis direction (up-down direction) is a direction orthogonal to the X-axis direction and the Y-axis direction and is a vertical direction.

It is to be noted that an expression like "along the Z-axis direction" or "along the XY plane" used in the present specification does not necessarily mean only a case in which an orientation of a member or a surface coincides with or is in parallel with the relevant direction or plane in a rigorous sense. Such an expression also means, for example, a case in which two elements are oriented in substantially the same direction while being slightly inclined with respect to each other or a case in which an angle of a member, an axis, a movement direction, and the like has a component of the relevant direction.

The wafer 4 that is a workpiece treated as a target to be ground in the grinding apparatus 2 is, for example, a disc-shaped wafer made of silicon and has devices such as ICs and LSI circuits formed on one surface thereof.

It is to be noted that there are no restrictions on the kind, material, shape, structure, size, and the like of the wafer 4 as the workpiece. For example, the wafer 4 may be a substrate (wafer) made of a semiconductor other than silicon (e.g., GaAs, InP, GaN, and SiC), sapphire, glass, ceramics, resin, metal, or the like. In addition, there are no restrictions on the kind, quantity, shape, structure, size, layout, and the like of the devices to be formed on the wafer 4. The wafer 4 may not necessarily have devices formed thereon.

The grinding apparatus 2 includes a holding table 6, a grinding unit 12, and moving units (an X moving unit 22 and a Z moving unit 24).

The holding table 6 is a mechanism for holding the wafer 4 as a platelike workpiece and is, for example, a chuck table. The holding table 6 as the chuck table has a disc-shaped table base 8 made of ceramics, metal, or the like and a suction plate 10 attached to the table base 8.

The suction plate 10 is, for example, a disc-shaped member made of porous ceramics. At an upper portion of the table base 8, a recess is formed in a disc shape corresponding in dimension to the suction plate 10, and the suction plate 10 is fitted and fixed in this recess. A flow path (not illustrated) is formed inside the table base 8, and one end of the flow path is connected to a lower surface of the suction plate 10.

Another end of the flow path provided inside the table base 8 is connected to a suction source (not illustrated) such as an ejector. When the suction source is actuated, negative pressure supplied through the flow path acts on an object such as the wafer 4 placed on an upper surface 10a of the suction plate 10. In this manner, the upper surface 10a of the suction plate 10 functions as a holding surface for holding the wafer 4 as the workpiece. It is to be noted that the suction plate 10 may be, for example, a platelike metal member having a plurality of holes penetrating the suction plate 10 vertically.

The upper surface of the suction plate 10 functioning as the holding surface 10a of the holding table 6 is formed in the shape of a conical surface with its central portion slightly protruding outward (toward a side opposite to the side of the table base 8; upward). A bottom surface (surface facing the side of the table base 8) of the suction plate 10 is substantially flat.

It is to be noted that, while the inclination of the holding surface (upper surface) 10a is exaggerated in FIG. 2 for convenience of explanation, the inclination in actuality may be so small that it is not recognizable with the naked eye. As specific numerical values, for example, in a case in which the diameter of the suction plate 10 is approximately 200 mm, a difference in height between the central portion and an outer peripheral portion of the suction plate 10 is approximately 20 μm.

When the disc-shaped wafer 4 is held under suction on the holding surface 10a of the conical surface shape, it is formed into a conical surface shape along the holding surface 10a as illustrated in FIG. 2 with a central portion of the wafer 4 slightly protruding upward as a vertex of the conical surface.

The grinding unit 12 for grinding the wafer 4 held on the holding table 6 is disposed in a space above the holding table 6.

The grinding unit 12 includes a spindle housing 14 and a spindle 16 that is a rotor housed in the spindle housing 14. The spindle 16 which is a columnar member is supported such that it is rotatable relative to the spindle housing 14 about an axis extending along the vertical direction (Z-axis direction).

A lower end side of the spindle 16 is exposed from the spindle housing 14, and a disc-shaped wheel mount is fixed to a tip of a lower end portion of the spindle 16. To a lower surface of the wheel mount, a disc-shaped grinding wheel 18 having a diameter substantially the same as that of the wheel mount is mounted. A plurality of grindstones 20 are fixed to a lower surface of the grinding wheel 18 over the whole circumference thereof. The grindstones 20 are thus attached to the spindle 16 as constituent elements of the grinding wheel 18.

Each of the grindstones 20 attached to the grinding wheel 18 is a stone having abrasive grains embedded in a bond material, for example. The bond material is, for example, a resin bond, a vitrified bond, a metal bond, or the like. Abrasive grains made of diamond, cubic boron nitride, or the like are dispersed in the bond material.

A rotational drive source (not illustrated) such as a motor is coupled to an upper end side of the spindle 16, and the spindle 16 is thus rotated together with the grinding wheel 18. When the rotational drive source is actuated, the spindle 16 is rotated, and the grindstones 20 attached to the lower surface of the grinding wheel 18 are rotated in such a manner as to have an annular locus around the rotational axis. At this time, lower ends of the grindstones 20 constitute an annular grinding surface. The orientation of the grinding surface constituted by the rotating grindstones 20 is along the orientation of the holding surface 10a of the holding table 6.

It is to be noted that the grinding surface constituted by the lower ends of the grindstones 20 forms a plane substantially orthogonal to the rotational axis of the spindle 16 while the holding surface 10a of the holding table 6 is formed in a conical surface shape as described above, and hence, the orientation of the grinding surface constituted by the grindstones 20 does not coincide with the orientation of the holding surface 10a of the holding table 6 in a rigorous sense.

The holding table 6 and the grinding unit 12 are movable relative to each other by the X moving unit 22 and the Z moving unit 24 functioning as the moving units.

The X moving unit 22 in the grinding apparatus 2 according to the present embodiment moves the holding table 6 along the X-axis direction. The Z moving unit 24 moves the grinding unit 12 along the Z-axis direction.

The X moving unit 22 includes guide rails 26, a movable table 28, a ball screw 30, and a rotational drive source 32.

The guide rails 26 are paired rodlike members fixed on an upper surface of a base of the grinding apparatus 2 and extending in parallel with each other along the X-axis direction. In FIG. 2, only one of the paired guide rails 26 is illustrated. On upper surfaces of the paired guide rails 26, the movable table 28 having a surface lying along a horizontal surface (XY plane) is attached slidably along a longitudinal direction of the guide rails 26.

Between the paired guide rails 26 extending in parallel with each other, there is disposed the ball screw 30 extending along the X-axis direction in parallel with the guide rails 26. A nut portion 34 is provided on a lower surface side of the movable table 28, and the ball screw 30 is rotatably coupled to the nut portion 34 through a ball (not illustrated).

The rotational drive source 32 such as a pulse motor is coupled to one end portion of the ball screw 30. When the rotational drive source 32 is actuated, the ball screw 30 rotates about its axis, and the movable table 28 is thus moved in the longitudinal direction (direction along the X-axis direction) of the guide rails 26.

On an upper surface of the movable table 28, a rotary unit 36 and an inclination adjustment unit 38 are mounted together with the holding table 6. The rotary unit 36 is a mechanism for rotating the holding table 6. The inclination adjustment unit 38 is a mechanism for adjusting an angle of the holding table 6.

Under the table base 8 of the holding table 6, a rotational axis extends downward from a bottom surface of the table base 8 along a direction orthogonal to the holding surface 10a. The rotary unit 36 includes a rotational drive source such as a motor, a driving pulley fixed to an output shaft of the rotational drive source, a driven pulley fixed to the rotational axis of the holding table 6, and an endless belt wound around the driving pulley and the driven pulley (all of which are not illustrated).

When the rotational drive source of the rotary unit 36 is actuated, its rotational force is transmitted through the output shaft, the driving pulley, the endless belt, and the driven pulley to the holding table 6, and the holding table 6 is thus rotated about an axis of the conical surface constituted by the holding surface 10a. The rotational axis of this rotation extends along the vertical direction (Z-axis direction), but the precise angle of the rotational axis is adjusted by the inclination adjustment unit 38 to be described next.

The holding table 6 is supported by the inclination adjustment unit 38 on the upper surface of the movable table 28. The inclination adjustment unit 38 includes one fixed shaft 38a and a plurality of movable shafts 38b, each of the shafts extending along the Z-axis direction. It is to be noted that, in FIG. 2, only one of the movable shafts 38b is illustrated.

The movable shaft 38b is formed to be extensible and contractible along the Z-axis direction. This makes it possible to have the holding table 6 inclined above the movable table 28 and to adjust the angle of the holding table 6.

At a position behind the X moving unit 22 and the holding table 6 (on the right side in FIG. 2) on the base of the grinding apparatus 2, provided is a projecting part projecting upward from the upper surface of the base. The projecting part has a front surface to which the grinding unit 12 is mounted through the Z moving unit 24.

The Z moving unit 24 includes guide rails 40, a movable table 42, a ball screw 44, and a rotational drive source 46.

The guide rails 40 are paired rodlike members fixed on the front surface of the projecting part of the base and extending in parallel with each other along the Z-axis direction. In FIG. 2, only one of the paired guide rails 40 is illustrated. To front surfaces of the paired guide rails 40 (surfaces on a side opposite to the side of surfaces attached to the projecting part of the base), the movable table 42 having a surface lying along a vertical surface (YZ plane) is attached slidably along a longitudinal direction of the guide rails 40.

Between the paired guide rails 40 extending in parallel with each other, there is disposed the ball screw 44 extending along the Z-axis direction in parallel with the guide rails 40. A nut portion 48 is provided on a back surface (rear surface) side of the movable table 42, and the ball screw 44 is rotatably coupled to the nut portion 48 through a ball (not illustrated).

The rotational drive source 46 such as a pulse motor is coupled to one end portion of the ball screw 44. When the rotational drive source 46 is actuated, the ball screw 44 rotates about its axis, and the movable table 42 is thus moved in the longitudinal direction (direction along the Z-axis direction) of the guide rails 40.

It is to be noted that the X moving unit 22 and the Z moving unit 24 functioning as the moving units are mechanisms for moving the holding table 6 and the grinding unit 12 relative to each other, and that how each moving unit performs the movement may appropriately be set as long as movements of respective portions required for grinding and other steps can suitably be preformed.

For example, the X moving unit 22 may move the holding table 6 and the grinding unit 12 relative to each other by moving the grinding unit 12 instead of moving the holding table 6. Alternatively, the X moving unit 22 may move both the holding table 6 and the grinding unit 12.

Similarly, the Z moving unit 24 may move the holding table 6 and the grinding unit 12 relative to each other by moving the holding table 6 instead of moving the grinding unit 12. Alternatively, the Z moving unit 24 may move both the holding table 6 and the grinding unit 12.

The grinding apparatus 2 further includes a processing liquid supply part (not illustrated). The processing liquid supply part is, for example, a nozzle for ejecting water as processing liquid, and supplies the wafer 4 and the grindstones 20 with water when grinding of the wafer 4 is performed. An ejecting port of the processing liquid supply part as the nozzle is, for example, provided above the holding surface 10a of the holding table 6. It is to be noted that the grinding apparatus 2 may include a processing liquid supply part having such a mechanism as to supply processing liquid through the grinding unit 12.

The respective units included in the grinding apparatus 2 (the holding table 6, the grinding unit 12, the moving units (the X moving unit 22 and the Z moving unit 24), the rotary unit 36, the inclination adjustment unit 38, and the like) are connected to a controller 50 illustrated in FIG. 1. The controller 50 in the present embodiment is a mechanism that monitors and controls operation of the respective units of the grinding apparatus 2, and is constituted by a computer, for example.

The computer constituting the controller 50 includes, for example, an information processing device that performs various kinds of information processing and a storage device that stores information. The information processing device is a central processing unit (CPU), for example. The storage device includes, for example, a main memory such as a dynamic random access memory (DRAM) and an auxiliary memory such as a hard disk drive and a flash memory. Functions of the controller 50 are, for example, implemented by the information processing device operating in accordance with programs (software) stored in the storage device.

The controller 50 is connected to an input/output section 52 that displays various kinds of information related to operation of the grinding apparatus 2 and receives inputs for operating the respective units.

The input/output section 52 is, for example, a display of a touch panel type. For example, the input/output section 52 displays thereon an operation screen for receiving inputs of various kinds of information, commands, and the like for the respective units of the grinding apparatus 2, and an operator can input information to the controller 50 by making a touch operation on the operation screen. It is to be noted that a device for displaying various kinds of information and another device for receiving operation inputs may be provided separately, for example, and the input/output section 52 may include a liquid crystal display connected to the controller 50 and an input device such as a mouse or a keyboard connected likewise to the controller 50.

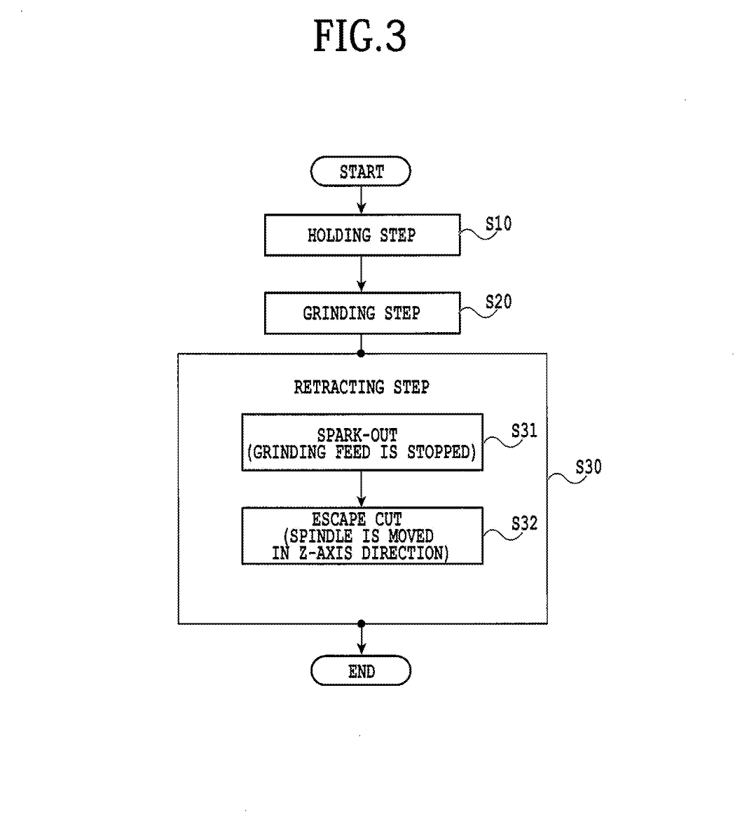

Described next is a procedure for grinding the wafer 4 by use of the grinding apparatus 2 described above. FIG. 3 is a flowchart describing an example of a procedure related to the grinding of the workpiece (wafer) 4 and manufacturing of a ground wafer by use of the grinding apparatus 2 illustrated in FIG. 1.

The procedure related to the grinding of the wafer 4 and the manufacturing of a ground wafer includes, for example, a holding step S10, a grinding step S20, and a retracting step S30 as illustrated in FIG. 3.

In the holding step S10, as illustrated in FIG. 2, the wafer 4 is held on the holding surface 10a of the holding table 6. The wafer 4 is placed on the holding surface 10a which is the upper surface of the suction plate 10, negative pressure is supplied from the suction source (not illustrated) to the suction plate 10, and the wafer 4 is thus held under suction on the holding surface 10a.

Subsequently, the grinding step S20 is performed. As illustrated in FIG. 2, the holding surface 10a of the holding table 6 has a conical surface shape, and an upper surface side of the wafer 4 held thereon (surface on a side opposite to the side of the surface held under suction on the holding surface 10a) also has a conical surface shape.

The moving units (the X moving unit 22 and the Z moving unit 24) move the holding table 6 and the grinding unit 12 individually, and the holding table 6 and the grinding unit 12 are positionally adjusted relative to each other such that a part of the annular locus formed by the grindstones 20 during the rotation of the spindle 16 overlaps the vertex of the conical surface of the holding surface 10a and the wafer 4 in plan view (in a field of view seen in the Z-axis direction; more precisely, in a field of view along directions of the relative movements of the holding table 6 and the grinding unit 12 by the Z moving unit 24).

Starting from this state, the holding table 6 and the spindle 16 approach each other along the Z-axis direction by the operation of the Z moving unit 24 while they are rotating independently. When the grindstones 20 of the grinding wheel 18 attached to the spindle 16 of the grinding unit 12 make contact with the upper surface of the wafer 4 held on the holding table 6, the wafer 4 starts to be ground. At the time of the grinding, water as the processing liquid is supplied from the processing liquid supply part (not illustrated).

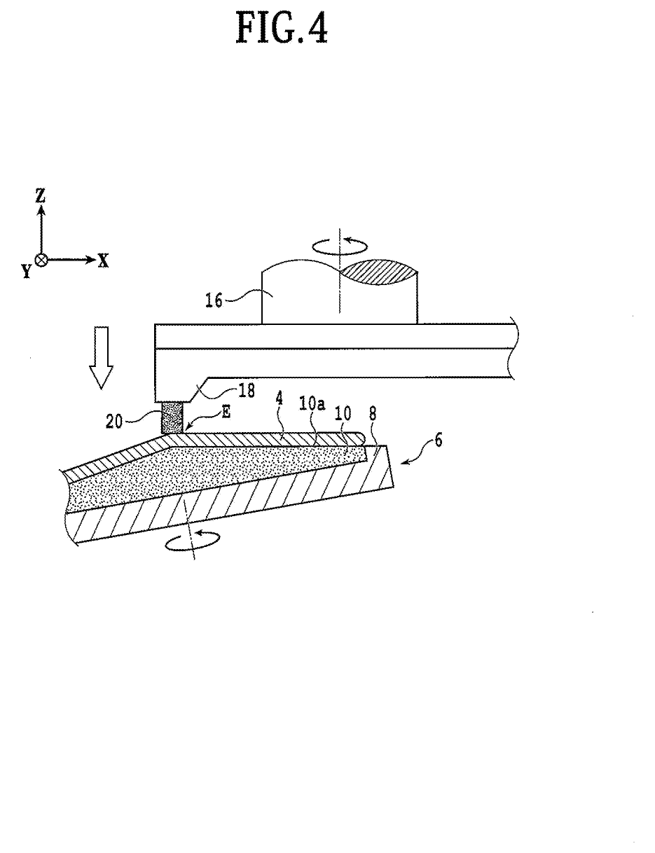

During the grinding, as indicated by a white arrow in FIG. 4, the grinding unit 12 is gradually moved downward along the Z-axis direction by the Z moving unit 24 in such a manner that the holding table 6 and the spindle 16 approach each other (grinding feed). FIG. 4 is a cross-sectional view schematically illustrating states of the grindstones 20 and the wafer 4 during the grinding.

Here, "grinding feed" in the present specification means feeding operation performed in grinding, and is operation of causing the holding table 6 and the spindle 16 to approach each other in such a manner that the workpiece (wafer) 4 held on the holding table 6 and the grindstones 20 of the grinding wheel 18 attached to the spindle 16 of the grinding unit 12 are pressed against each other.

At the time of the grinding, the rotational axis of the holding table 6 and the rotational axis of the spindle 16 have a positional relation of extending along each other (however, the rotational axis of the holding table 6 is slightly inclined with respect to the Z-axis, and the two rotational axes are not in parallel with each other in a rigorous sense). In the grinding feed, as the wafer 4 and the grindstones 20 wear, the holding table 6 and the spindle 16 are moved relative to each other by the Z moving unit 24 in such a manner as to approach each other in directions along the rotational axis of the spindle 16 (directions along the Z-axis direction).

It is to be noted that, in the grinding apparatus 2 describe above, the spindle 16 is moved along the Z-axis direction, so that the spindle 16 and the holding table 6 are moved relative to each other in the directions along the Z-axis direction. Alternatively, the holding table 6 may be moved instead of the spindle 16, or both the holding table 6 and the spindle 16 may be moved.

The locus of the lower ends of the rotating grindstones 20 forms the annular grinding surface having a width corresponding to that of the grindstones 20 (dimension when seen in a radial direction of the grinding wheel 18), the annular grinding surface lying along the horizontal surface (XY plane). One point on the annular locus is located at the vertex of the conical surface shape of the wafer 4 held on the holding surface 10a of the holding table 6. That is, the lower ends of the rotating grindstones 20 make contact with the wafer 4 at least at the vertex of the conical surface shape of the wafer 4.

The wafer 4 and the grindstones 20 in contact with each other are pressed against each other in the directions along the Z-axis direction by the grinding feed, and this generates stress inside each of the wafer 4 and the grindstones 20. The grindstones 20 formed by a bond material with abrasive grains embedded therein are pressed against the surface of the wafer 4 while being deformed in such a manner as to be crushed by the force received from the surface of the wafer 4. In particular, in a case in which the bond material contained in the grindstones 20 is resin like a resin bond, the deformation of the grindstones 20 is significant.

After the wafer 4 is ground to have a desired thickness by the grinding step S20, the retracting step S30 is performed. In the retracting step S30, the grinding feed of causing the holding table 6 and the spindle 16 to approach each other is stopped, and the holding table 6 and the grinding unit 12 are then moved in such a manner that the wafer 4 and the grindstones 20 are separated from each other.

At this time, operation steps generally called spark-out (step S31) and escape cut (step S32) are performed. Spark-out is operation that is performed after the grinding involving the grinding feed (grinding step S20) and that rotates the wafer 4 and the grindstones 20 while stopping the grinding feed. Escape cut is operation that moves the wafer 4 and the grindstones 20 in the directions opposite to the directions of the grinding feed to separate the wafer 4 and the grindstones 20 from each other while rotating the wafer 4 and the grindstones 20.

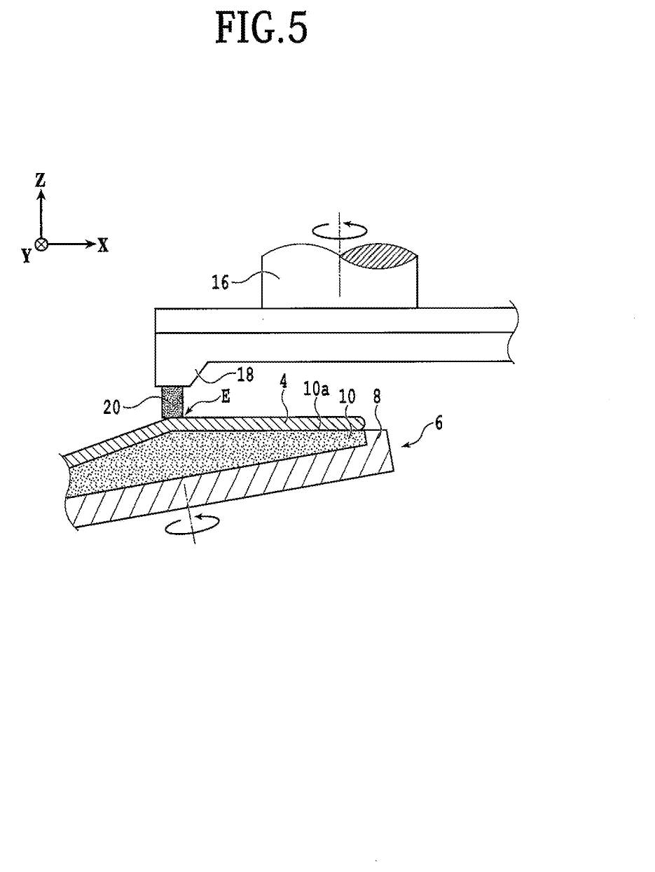

FIG. 5 is a cross-sectional view schematically illustrating, as a reference example, exemplary states of the grindstones 20 and the wafer 4 in the spark-out.

In the spark-out (step S31), while the grinding feed (the movement of the spindle 16 along the Z-axis direction) is stopped, the rotations of the wafer 4 and the grindstones 20 are continued. Although the grinding feed has been stopped, the positions of the wafer 4 and the grindstones 20 have not been moved from those at the end of the grinding step S20. Therefore, the grindstones 20 pressed against the wafer 4 are still in the state of being deformed in such a manner as to be crushed, and hence, the grindstones 20 press the abrasive grains against the wafer 4 due to force for restoring its shape to its original state from the crushed state.

When the wafer 4 and the grindstones 20 are rotated in this state, the wafer 4 is slightly ground, and the grindstones 20 wear gradually. Consequently, the shape of the material of the grindstones 20 having been deformed in such a manner as to be crushed is restored gradually, and the stress generated inside the grindstones 20 starts to be released.

Although not illustrated in FIG. 5, in a case in which a soft protective member such as a back grinding (BG) tape is applied to a back surface of the wafer 4 (surface on the side facing the holding table 6), for example, the protective member has also been compressed by the grinding feed in the grinding step S20. In the spark-out, the wafer 4 is ground in the manner described above with the grinding feed stopped, so that the force for compressing the protective member also starts to be released.

After the spark-out (step S31) has been performed by taking appropriate time, the escape cut (step S32) is subsequently performed.

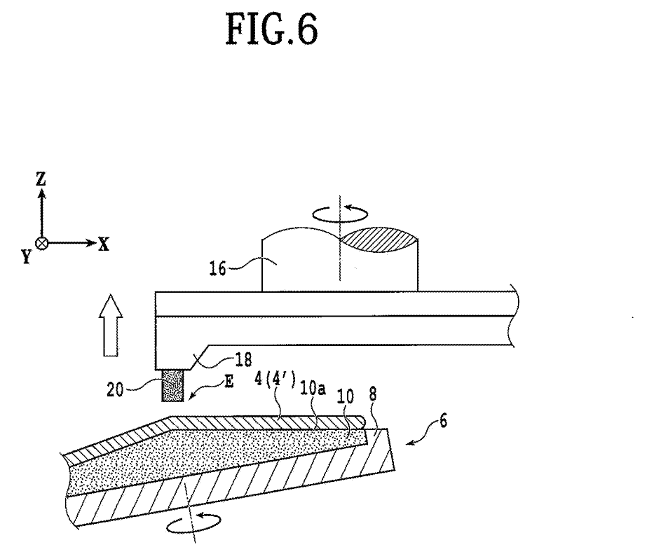

FIG. 6 is a cross-sectional view schematically illustrating, as a reference example, exemplary states of the grindstones 20 and the wafer 4 in the escape cut.

In the escape cut (step S32), the wafer 4 and the grindstones 20 are moved in the directions opposite to the directions of the grinding feed while the rotations of the wafer 4 and the grindstones 20 are continued. That is, in the present embodiment, the spindle 16 is moved upward along the Z-axis direction.

In a short period of time after the start of the escape cut, the wafer 4 and the grindstones 20 are in contact with each other. When the grindstones 20 and the material of the protective member on the back surface of the wafer 4, which grindstones 20 and material have been compressed by the grinding feed, are released from the compressive force, the wafer 4 and the grindstones 20 are separated from each other, and the grinding of the wafer 4 is completely ended. In this manner, a ground wafer 4' is manufactured.

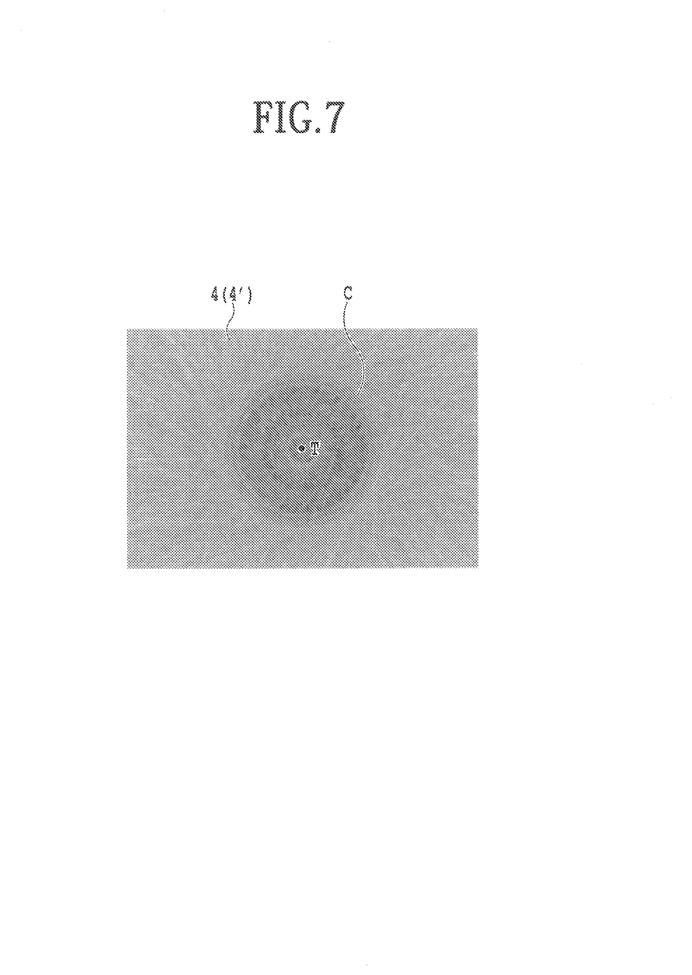

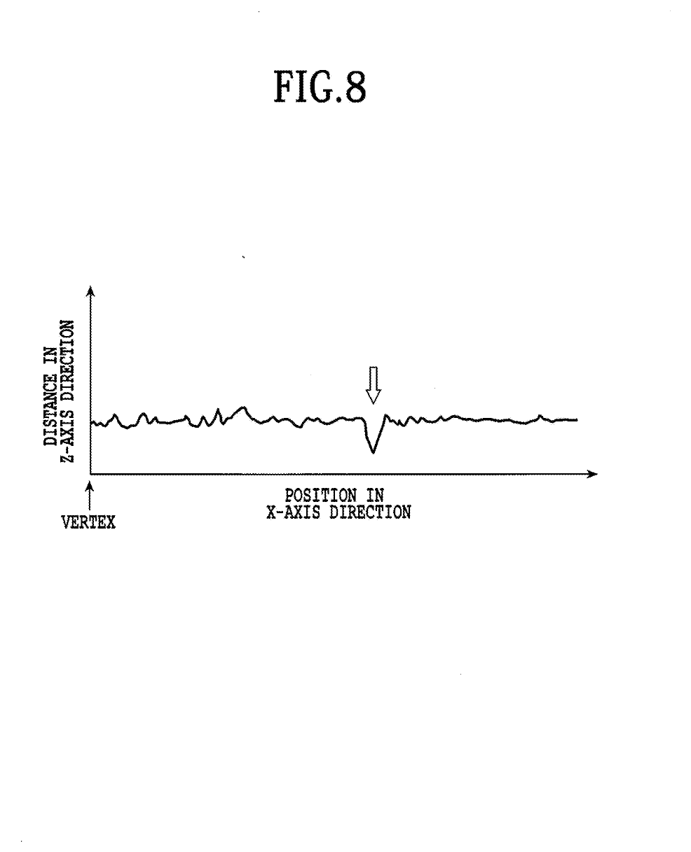

Operation in general spark-out and escape cut in the retracting step S30 has been described so far. When the retracting step S30 has been performed through such operation, for example, there may appear such a shape as depicted in FIG. 7 and FIG. 8 on the surface of the wafer 4 having been ground.

FIG. 7 is a photomicrograph depicting, as a reference example, an exemplary state of the surface of the workpiece (ground wafer) 4' obtained after completion of the grinding step S20 and the retracting step S30. In the photomicrograph, a point indicated by a reference symbol T is a portion corresponding to the vertex of the conical wafer 4 held on the holding table 6. In addition, there appears a circular groove shape (indicated by a reference symbol C in the photomicrograph; hereinafter referred to as a "circular groove") around the vertex T.

FIG. 8 is a chart illustrating a measurement result of the shape of the surface of the workpiece (ground wafer) 4' depicted in FIG. 7. The shape of the surface of the wafer 4' having been ground is measured by a laser sensor installed above the wafer 4'. The upper surface of the wafer 4' disposed lying along the horizontal direction is irradiated with measurement light emitted from the laser sensor, the measurement light advancing along the vertical direction, and the distance between the laser sensor and the surface of the wafer 4' is measured while the position of the laser sensor is moved along a radial direction of the wafer 4'.

In the chart of FIG. 8, the horizontal axis represents the distance from the center (vertex T) of the wafer 4' (position in the X-axis direction), and the vertical axis represents the distance from the laser sensor to the surface of the wafer 4' (position in the Z-axis direction).

In the chart, there is a downward peak at a portion indicated by a white arrow (position at approximately 2.5 mm from the center), and this peak corresponds to the position of the circular groove C depicted in FIG. 7. Further, the position of the circular groove C corresponds to a portion on the surface of the wafer 4 with which portion an edge of the grindstones 20 makes contact in the grinding step S20 through the retracting step S30, that is, corresponds to a portion on the surface of the wafer 4 with which portion an inner edge (hereinafter referred to as an "inner edge E") in the radial direction of the annular grinding surface formed by the rotation of the grindstones 20 makes contact (refer to FIG. 4 to FIG. 6).

In a grinding method like the one described above in which the wafer 4 and the grindstones 20 are brought into contact with each other while they are being rotated independently (such a method is called infeed grinding), saw marks are generated radially in most areas of the surface of the wafer 4'. In addition, depending on conditions, there may specifically appear such a shape as the circular groove C depicted in FIG. 7 and FIG. 8 in the central portion of the wafer 4'. This is likely to occur especially in a case in which the grindstones 20 containing an elastic material like a resin bond as the bond material are used in grinding.

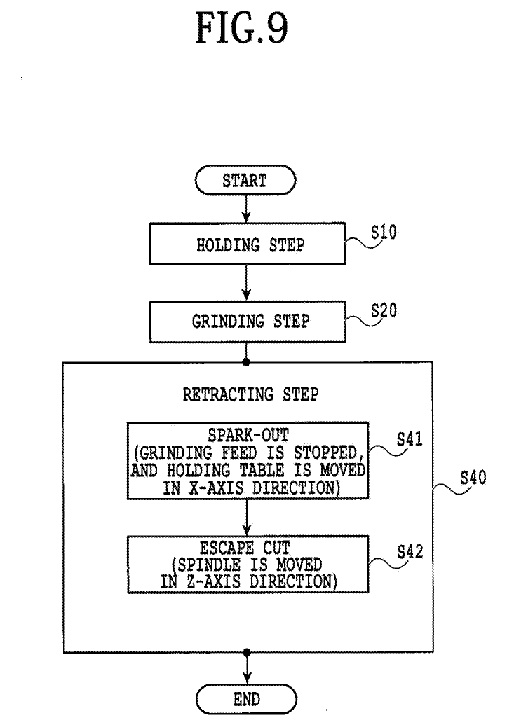

The inventor and others of the present application have found out that occurrence of such circular saw marks (circular groove C) can be reduced by devising operation in the spark-out and the escape cut. The method thus devised is described with reference to FIG. 9 and FIG. 10 to FIG. 13.

FIG. 9 is a flowchart describing another example of the procedure related to the grinding of the workpiece (wafer) 4 and the manufacturing of a ground wafer by use of the grinding apparatus 2 illustrated in FIG. 1. In the procedure illustrated in FIG. 9, the holding step S10 and the grinding step S20 are performed as with those in the procedure illustrated in FIG. 3, but contents of operation performed in a retracting step S40 (spark-out (step S41) and escape cut (step S42)) are different from those of the retracting step S30 in the procedure of FIG. 3.

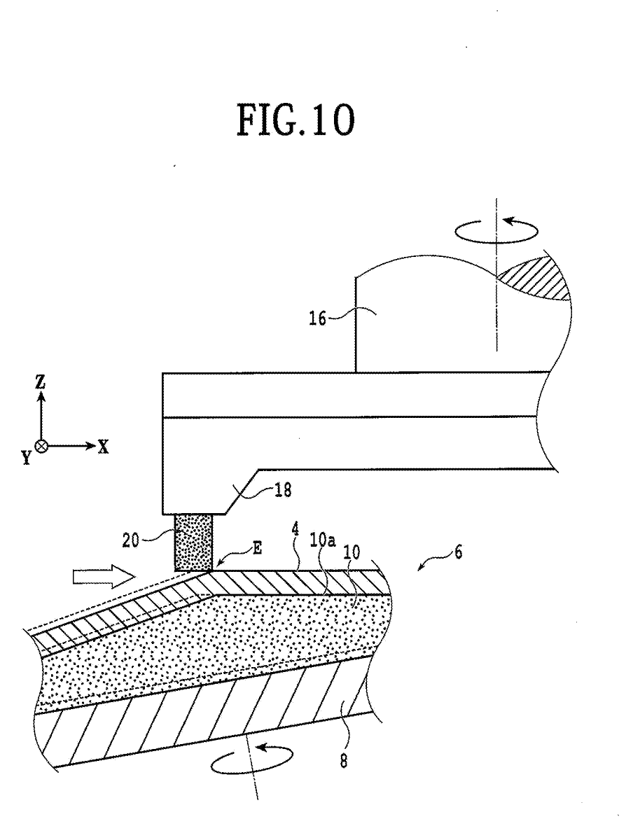

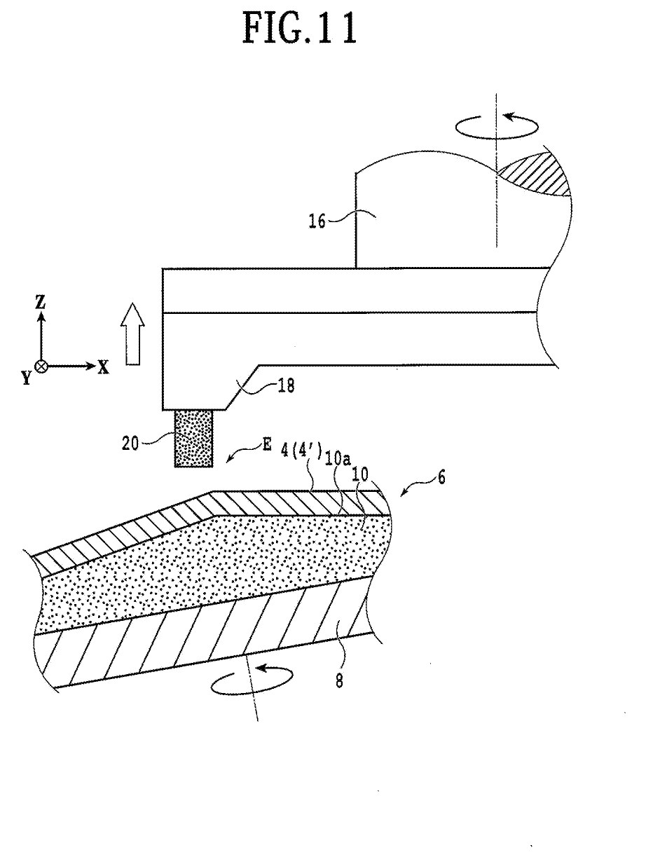

FIG. 10 is a cross-sectional view schematically illustrating exemplary states of the grindstones 20 and the workpiece (wafer) 4 in the spark-out (step S41) in the procedure of FIG. 9. FIG. 11 is a cross-sectional view schematically illustrating exemplary states of the grindstones 20 and the workpiece (wafer) 4 in the escape cut (step S42) in the procedure of FIG. 9.

In the spark-out (step S41) of the retracting step S40 in the procedure of FIG. 9, as indicated by a white arrow in FIG. 10, the holding table 6 is moved along the horizontal direction (X-axis direction), and the spindle 16 and the holding table 6 are thus moved relative to each other in directions along the grinding surface of the grindstones 20.

The directions of the relative movements of the spindle 16 and the holding table 6 at this time are directions in which a point of intersection between the grinding surface and the rotational axis of the holding table 6 and the wafer 4 and a point of intersection between the grinding surface and the rotational axis of the spindle 16 and the grindstones 20 approach each other in plan view (in a field of view seen from a direction along the rotational axis), and are directions in which the inner edge E of the portion of the grinding surface of the grindstones 20, the portion being in contact with the vertex of the wafer 4 in the conical surface shape, approaches the vertex of the wafer 4.

It is to be noted that, in the grinding apparatus 2 describe above, the holding table 6 is moved along the X-axis direction, so that the spindle 16 and the holding table 6 are moved relative to each other in the directions along the grinding surface of the grindstones 20. At this time, alternatively, the spindle 16 may be moved instead of the holding table 6, or both the holding table 6 and the spindle 16 may be moved. Further, the movement may be performed in a direction (direction along the Y-axis direction) intersecting the X-axis direction, so that the holding table 6 and the spindle 16 are moved relative to each other in directions along the grinding surface of the grindstones 20.

Thereafter, the escape cut (step S42) is performed as illustrated in FIG. 11. In the preceding spark-out, the wafer 4 and the grindstones 20 have been shifted from each other in position in the X-axis direction. In the escape cut (step S42), from that positional relation, the spindle 16 is moved upward (in a direction opposite to the grinding feed direction) along the Z-axis direction, and the wafer 4 and the grindstones 20 are thus separated from each other along the Z-axis direction. In this manner, the ground wafer 4' is manufactured.

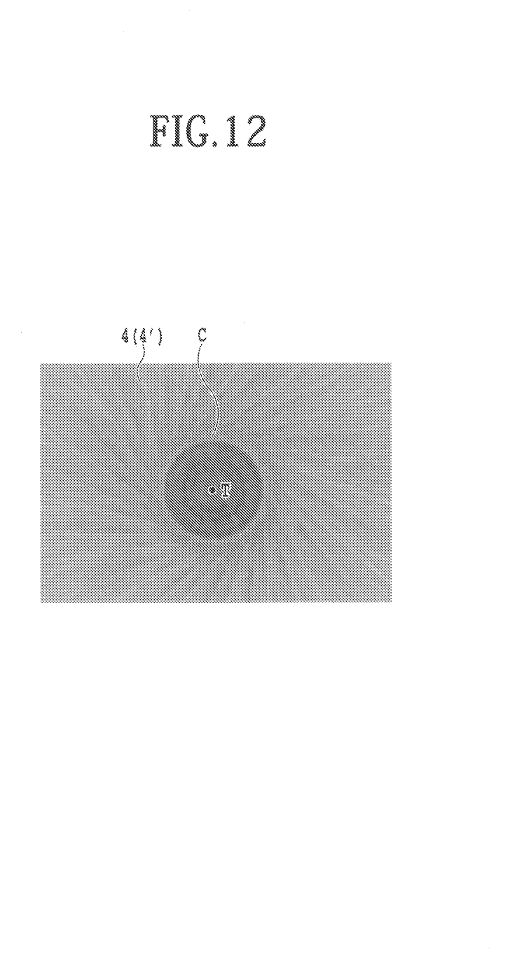

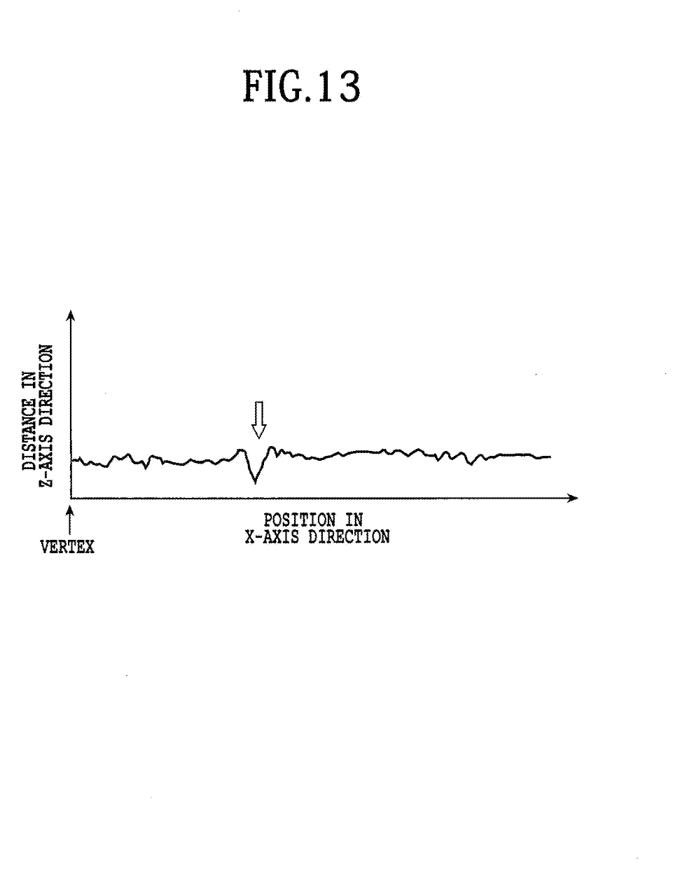

FIG. 12 and FIG. 13 depict an exemplary state of the surface of the wafer 4' obtained after the grinding has been performed according to the procedure described above. FIG. 12 is a photomicrograph depicting an exemplary state of the surface of the workpiece (ground wafer) 4' obtained after completion of the retracting step S40 in the procedure illustrated in FIG. 9. FIG. 13 is a chart illustrating a measurement result of the shape of the surface of the workpiece (ground wafer) 4' depicted in FIG. 12, the chart being created in a manner same as that of the chart illustrated in FIG. 8.

In the photomicrograph of FIG. 12, the diameter of the circular groove C is apparently smaller than that in the photomicrograph of FIG. 7. In the chart of FIG. 13 as well, a downward peak (indicated by a white arrow in the chart) corresponding to the circular groove C is positioned closer to the vertex of the wafer 4 than in the chart of FIG. 8.

In the procedure illustrated in FIG. 9 to FIG. 11, the holding table 6 and the spindle 16 are moved relative to each other in the directions along the X-axis direction in the spark-out (step S41), so that the wafer 4 and the grindstones 20 are shifted from each other in position. At the end of the spark-out, the position of the inner edge E of the grinding surface constituted by the grindstones 20 has approached the vertex of the wafer 4 as illustrated in FIG. 10. The position of the circular groove C depicted in FIG. 12 and FIG. 13 corresponds to the position of the inner edge E of the grinding surface at the end of the spark-out.

Accordingly, it is considered that, by moving the holding table 6 and the spindle 16 relative to each other in the spark-out in such a manner as to cause the inner edge E of the grinding surface constituted by the grindstones 20 to gradually approach the vertex of the conical wafer 4, the diameter of the circular groove C can be made smaller, thereby narrowing the range of the area in which the circular groove C is formed.

It is further considered that, by making the inner edge E of the grinding surface coincide with the position of the vertex of the wafer 4 at the end of the spark-out or making the inner edge E of the grinding surface cross the position of the vertex of the wafer 4 in the middle of the spark-out, even the occurrence of a noticeable circular groove can be suppressed.

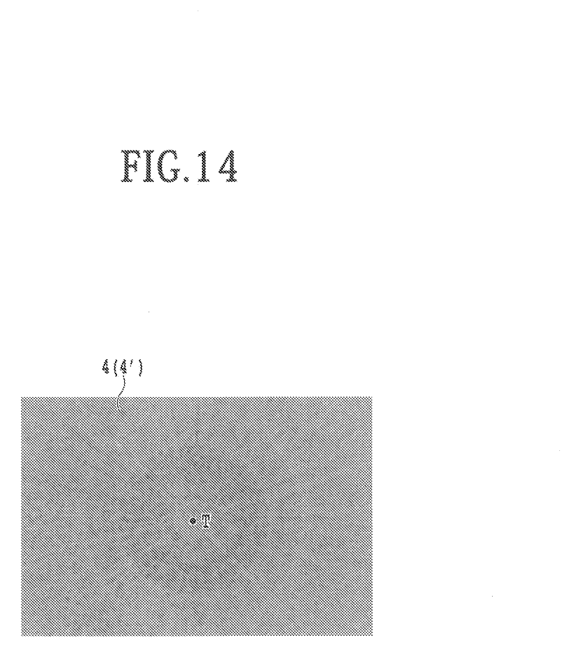

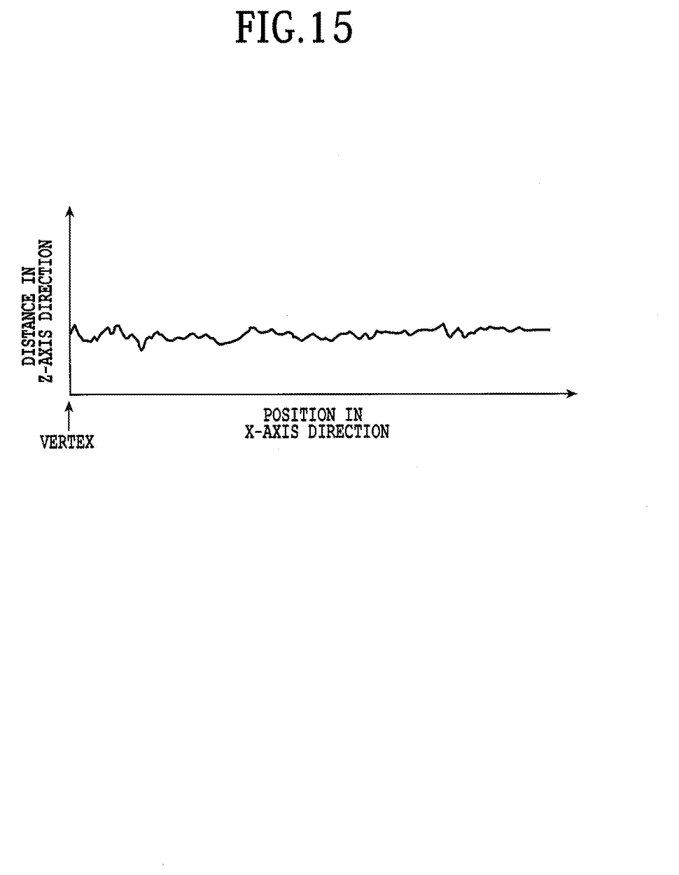

Therefore, the grinding was performed with the relative movement amount between the holding table 6 and the spindle 16 in the spark-out adjusted such that the inner edge E of the grinding surface coincides with the position of the vertex of the wafer 4 at the end of the spark-out (step S41) in the procedure illustrated in FIG. 9, and a result of the grinding is indicated in a photograph in FIG. 14 and a chart in FIG. 15. FIG. 14 is a photomicrograph depicting an exemplary state of the surface of the workpiece (ground wafer) 4' obtained after completion of the retracting step S40 in such a procedure. FIG. 15 is a chart illustrating a measurement result of the shape of the surface of the workpiece (ground wafer) 4' depicted in FIG. 14, the chart being created in a manner same as that of the chart illustrated in FIG. 8.

In the photomicrograph of FIG. 14, there is a visible circular shape of saw marks around the vertex T of the wafer 4, but this circular shape is fainter than the circular grooves C in FIG. 7 and FIG. 12, and there is no apparent groove-like shape formed. In addition, in the chart of FIG. 15, a downward peak more conspicuous than other areas cannot be found around the vertex.

Accordingly, in the procedure illustrated in FIG. 9 to FIG. 11, the wafer 4 and the grindstones 20 are moved relative to each other along the grinding surface in the spark-out, so that the area in which the circular groove C appears can be narrowed, or the circular shape thereof can be made fainter.

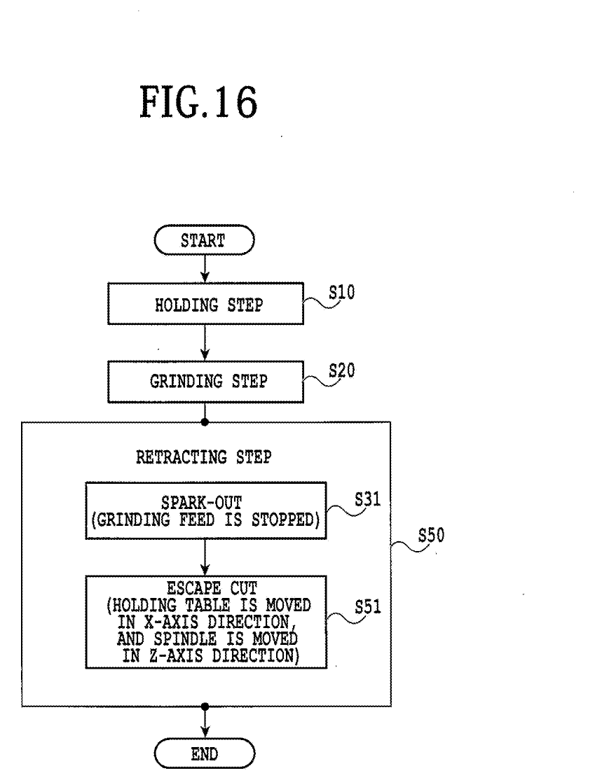

FIG. 16 is a flowchart describing a further example of the procedure related to the grinding of the workpiece (wafer) 4 and the manufacturing of a ground wafer by use of the grinding apparatus 2 illustrated in FIG. 1. In the procedure illustrated in FIG. 16, the holding step S10, the grinding step S20, and the spark-out (step S31) of a retracting step S50 are performed in a manner same as those in the procedure illustrated in FIG. 3, but contents of escape cut (step S51) following the spark-out are different from those of the escape cut (step S32) in the procedure of in FIG. 3.

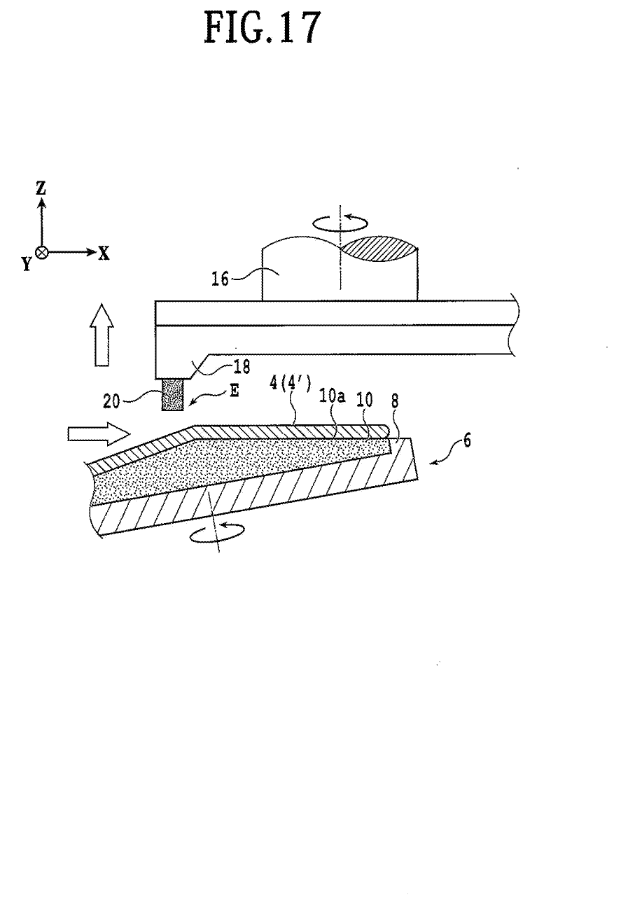

FIG. 17 is a cross-sectional view schematically illustrating exemplary states of the grindstones 20 and the workpiece (wafer) 4 in the escape cut (step S51) in the procedure of FIG. 16.

In the escape cut (step S51) of the retracting step S50 in the procedure of FIG. 16, as indicated by white arrows in FIG. 17, the holding table 6 is moved along the horizontal direction (X-axis direction) while the spindle 16 is moved along the vertical direction (Z-axis direction), so that the spindle 16 and the holding table 6 are moved relative to each other in the directions along the grinding surface of the grindstones 20 while being separated from each other in the directions along the rotational axis of the spindle 16. In this manner, the ground wafer 4' is manufactured.

The directions of the relative movements of the spindle 16 and the holding table 6 along the X-axis direction at this time are directions in which a point of intersection between the grinding surface and the rotational axis of the holding table 6 and the wafer 4 and a point of intersection between the grinding surface and the rotational axis of the spindle 16 and the grindstones 20 approach each other in plan view (in the field of view seen from the direction along the rotational axis), and are directions in which the inner edge E of a portion of the grinding surface of the grindstones 20, the portion being in contact with the vertex of the wafer 4 in the conical surface shape, approaches the vertex of the wafer 4. In addition, the directions of the relative movements of the spindle 16 and the holding table 6 along the Z-axis direction at this time are directions in which the holding table 6 and the wafer 4 on one hand and the spindle 16 and the grindstones 20 on the other hand are moved away from each other.

It is to be noted that, in the grinding apparatus 2 describe above, in the relative movements of the holding table 6 and the spindle 16 in the escape cut as illustrated in FIG. 17, the movements along the horizontal direction (X-axis direction) (movements along the grinding surface of the grindstones 20) are made by the X moving unit 22 causing the holding table 6 to move, while the movements along the vertical direction (Z-axis direction) (movements along the respective rotational axes of the holding table 6 and the spindle 16) are made by the Z moving unit 24 causing the spindle 16 to move. Alternatively, the spindle 16 may be moved in the movements along the horizontal direction, and the holding table 6 may be moved in the movements along the vertical direction.

Further alternatively, both the holding table 6 and the spindle 16 may be moved in the movements along the horizontal direction, and both the holding table 6 and the spindle 16 may be moved in the movements along the vertical direction.

Furthermore, it is also possible that the grinding apparatus 2 includes a mechanism for causing at least one of the holding table 6 or the spindle 16 to move in an oblique direction intersecting both the horizontal direction and the vertical direction, and that the movements along the horizontal direction and the movements along the vertical direction are achieved by the single mechanism.

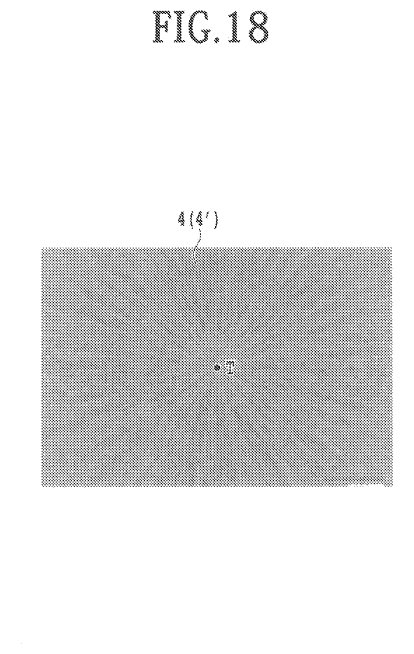

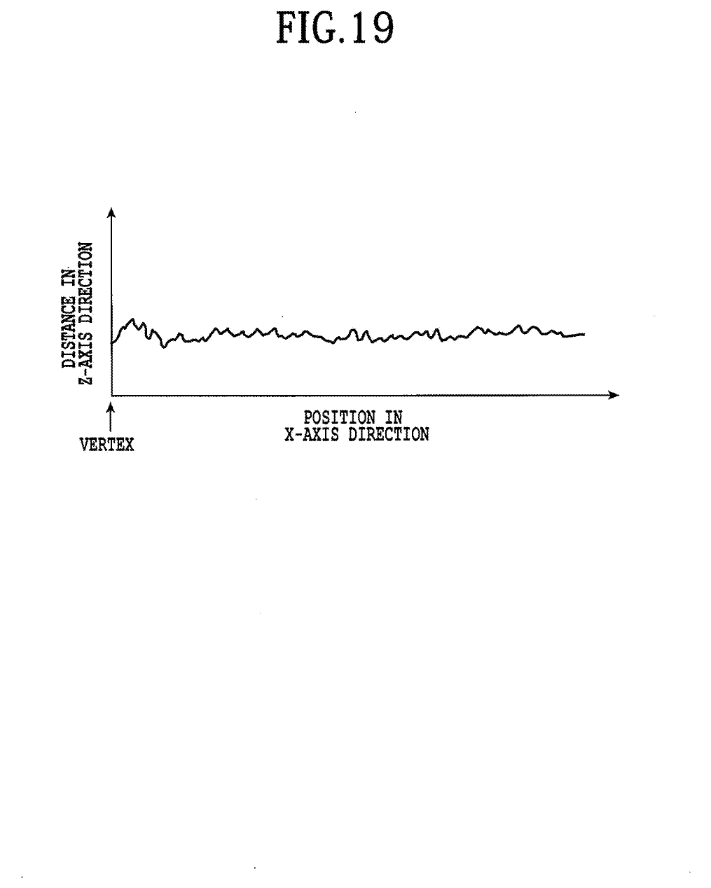

FIG. 18 and FIG. 19 depict an exemplary state of the surface of the workpiece (ground wafer) 4' obtained after the grinding has been performed according to the procedure described above. FIG. 18 is a photomicrograph depicting an exemplary state of the surface of the workpiece (ground wafer) 4' obtained after completion of the retracting step S50 in the procedure illustrated in FIG. 16. FIG. 19 is a chart illustrating a measurement result of the shape of the surface of the workpiece (ground wafer) 4' depicted in FIG. 18, the chart being created in a manner same as that of the chart illustrated in FIG. 8.

On the surface of the wafer 4 (ground wafer 4') depicted in FIG. 18 and FIG. 19, there is little circular shape found around the vertex T, and only radial saw marks from the vertex T are observed as depicted in FIG. 18.

In this manner, in the procedure illustrated in FIG. 16, the wafer 4 and the grindstones 20 are moved relative to each other in the directions along the grinding surface and in the directions along the rotational axes in the escape cut, so that the occurrence of circular saw marks can be suppressed.

As described above, in the grinding of the workpiece (wafer) 4, in the retracting step S40 or S50 following the grinding step S20, the grinding feed by the moving units 22 and 24 is stopped, and the holding table 6 and the spindle 16 are moved relative to each other in the directions intersecting the rotational axis of the spindle 16 while being rotated, so that a further suitable surface shape can be realized on the workpiece (ground wafer) 4'.

It is to be noted that the procedure illustrated in FIG. 9 and the procedure illustrated in FIG. 16 may be combined to perform the grinding of the wafer 4. For example, the moving units 22 and 24 may be operated such that, after the wafer 4 and the grindstones 20 are first moved relative to each other along the grinding surface in the spark-out, the wafer 4 and the grindstones 20 are moved relative to each other in the directions along the grinding surface while being moved relative to each other in the directions intersecting the grinding surface (directions along the rotational axes) in the escape cut.

Besides, the structures, methods, and the like according to the above embodiment are not limited to those described in the embodiment and may be modified as appropriate without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding method for grinding a workpiece by use of a grinding apparatus,
the grinding apparatus including a holding table that has a holding surface of a conical surface shape and is rotatable about an axis intersecting the holding surface, a grinding unit that includes a spindle to which grindstones are attached and grinds the workpiece held on the holding surface of the holding table by bringing the grindstones into contact with the workpiece while causing the grindstones to rotate in such a manner as to form a grinding surface lying along the holding surface, and a moving unit that moves the holding table and the grindstones relative to each other,
the grinding method comprising:
holding the workpiece on the holding surface of the holding table;
grinding the workpiece held on the holding surface by performing grinding feed in which the moving unit causes the holding table and the spindle to approach each other in directions along a rotational axis of the spindle in a state in which the workpiece and the grindstones are in contact with each other while the holding table and the spindle are independently being rotated with respective rotational axes extending along each other; and,
after the grinding the workpiece, stopping the grinding feed by the moving unit and moving the holding table and the spindle relative to each other in directions intersecting the rotational axis of the spindle while rotating the holding table and the spindle.

2. The grinding method according to claim 1, wherein, in the grinding the workpiece, a part of a locus formed by the grindstones is located at a vertex of the workpiece that is held on the holding surface of the holding table and formed in a conical surface shape.

3. The grinding method according to claim 1, wherein, in the moving the holding table and the spindle relative to each other in the directions intersecting the rotational axis of the spindle, the spindle and the holding table are moved relative to each other in directions along the grinding surface of the grindstones.

4. The grinding method according to claim 1, wherein, in the moving the holding table and the spindle relative to each other in the directions intersecting the rotational axis of the spindle, the spindle and the holding table are separated from each other in the directions along the rotational axis of the spindle while being moved relative to each other in directions along the grinding surface of the grindstones.

5. The grinding method according to claim 1, wherein the grindstones include a resin bond as a bond material.

6. The grinding method according to claim 2, wherein the grindstones include a resin bond as a bond material.

7. The grinding method according to claim 3, wherein the grindstones include a resin bond as a bond material.

8. The grinding method according to claim 4, wherein the grindstones include a resin bond as a bond material.

9. A ground wafer manufacturing method for manufacturing a ground wafer by use of a grinding method for grinding a workpiece by use of a grinding apparatus,
the grinding apparatus including a holding table that has a holding surface of a conical surface shape and is rotatable about an axis intersecting the holding surface, a grinding unit that includes a spindle to which grindstones are attached and grinds the workpiece held on the holding surface of the holding table by bringing the grindstones into contact with the workpiece while causing the grindstones to rotate in such a manner as to form a grinding surface lying along the holding surface, and a moving unit that moves the holding table and the grindstones relative to each other,
the grinding method including
holding the workpiece on the holding surface of the holding table,
grinding the workpiece held on the holding surface by performing grinding feed in which the moving unit causes the holding table and the spindle to approach each other in directions along a rotational axis of the spindle in a state in which the workpiece and the grindstones are in contact with each other while the holding table and the spindle are independently being rotated with respective rotational axes extending along each other, and,
after the grinding the workpiece, stopping the grinding feed by the moving unit and moving the holding table and the spindle relative to each other in directions intersecting the rotational axis of the spindle while rotating the holding table and the spindle,
wherein the workpiece is a platelike wafer.
